(19) United States
(12) Patent Application Publication
(10) Pub. No.: US 2014/0367838 A1
(43) Pub. Date: Dec. 18, 2014

(54) LEADFRAME WITH LEAD OF VARYING THICKNESS

(71) Applicant: Texas Instruments Incorporated, Dallas, TX (US)

(72) Inventors: Donald Charles Abbott, Norton, MA (US); Masood Murtuza, Sugar Land, TX (US)

(21) Appl. No.: 13/918,675

(22) Filed: Jun. 14, 2013

(51) Int. Cl. H01L 23/495; H01L 21/48; H01L 23/00

(52) U.S. Cl. CPC H01L 23/49575; H01L 24/80; H01L 23/49503; H01L 21/4842; H01L 2224/85
USPC 257/676; 438/123; 174/261; 174/257; 29/827

(57) ABSTRACT

A leadframe that includes a die attachment pad and a lead having a bondwire attach portion with a thickness less than 50% of the thickness of an adjacent portion of the lead. Also a method of forming a leadframe includes forming a lead having a bond wire attach portion with an original thickness and coining the bond wire attach portion to a thickness less than 50% of the original thickness. An integrated circuit package and a method of forming an integrated circuit package are also disclosed.

### BACKGROUND

Semiconductor devices, to be useful, must be electrically connected to one another or to other electronic devices or to interconnect boards such as printed circuit boards and carrier boards. Leadframes made from conductive metal such as copper alloys are often used to electrically connect semiconductor devices to other electronic devices. One popular and flexible method of connecting semiconductors devices to leadframes and/or other electronics is wire bonding. Bondwires usually consist of aluminum, copper or gold. Bond wire diameters typically range from about 0.8 mils to several hundred micrometers in high-power applications. There are two basic types of wire bonding—ball bonding and wedge bonding.

Ball bonding usually uses a combination of heat, pressure and ultrasonic energy. In ball bonding, a small molten ball is formed at the end of the bondwire by application of a high voltage charge through a tool holding and dispensing the wire known as a capillary. This ball is placed in contact with the electrical contact surface of a chip that is usually copper or aluminum. A combination of heat, pressure and ultrasonic energy is then applied which creates a weld between the ball and the metal surface that it contacts. The ball bond is sometimes referred to as the first bond because it is usually the first bond made in wire bonding of an IC chip/die to a leadframe.

In a die leadframe interconnection, the type of wire bond that is generally used to connect the second end of the bond wire to the leadframe is a called a stitch or wedge bond or sometimes a second bond. It is formed by crushing the end of the bondwire between the leadframe and the tip of a capillary tool. The leadframe is typically heated and ultrasonic energy and force are applied during the stitch bonding process.

A leadframe often forms part of the electrical connection between a semiconductor device and other electronics. In some cases the die and bond wires connecting it to a leadframe are encapsulated within a hard protective shell that is typically formed by a molding operation. One or more surfaces of lead portions of the leadframe are not covered by the protective shell and may be electrically and mechanically connected to external circuits. The combination of an integrated circuit (“IC”) die, leadframe, bond wires and encapsulating material is generally referred to as an integrated circuit package (IC package).

### BRIEF DESCRIPTION OF THE DRAWINGS

FIG. 1 is a top plan view of a lead frame.

FIG. 2 is a detail side elevation view of the lead frame of FIG. 1.

FIG. 3 is a detail end elevation view of the lead shown in FIG. 2.

FIG. 4 is a partially cutaway elevation view of an integrated circuit package with the lead frame shown in FIG. 1.

FIG. 5 is a detail of FIG. 4 showing a broken bond wire and a broken stitch bond.

FIG. 6 is a side elevation view of an example embodiment of a new lead configuration.

FIG. 7 is an end view of the lead of FIG. 6.

FIG. 8 is a partially cutaway elevation view of an example embodiment of integrated circuit package having the lead illustrated in FIGS. 6 and 7.

FIG. 9 is a top plan view of an example embodiment of a lead having an increased tip width due to coining.

FIG. 10 is a top plan view of an example embodiment of a lead having a reduced width tip prior to coining.

FIG. 11 is a top plan view of an example embodiment of a lead having an end portion thereof encompassed by restraining walls.

FIG. 12 is a detail side elevation view of an example embodiment of a lead having a coined portion provided at an intermediate portion of the lead.

FIG. 13 is a flow chart of an example embodiment of a method of forming a lead frame.

FIG. 14 is a flow chart of an example embodiment of a method of forming an integrated circuit package.

### DETAILED DESCRIPTION

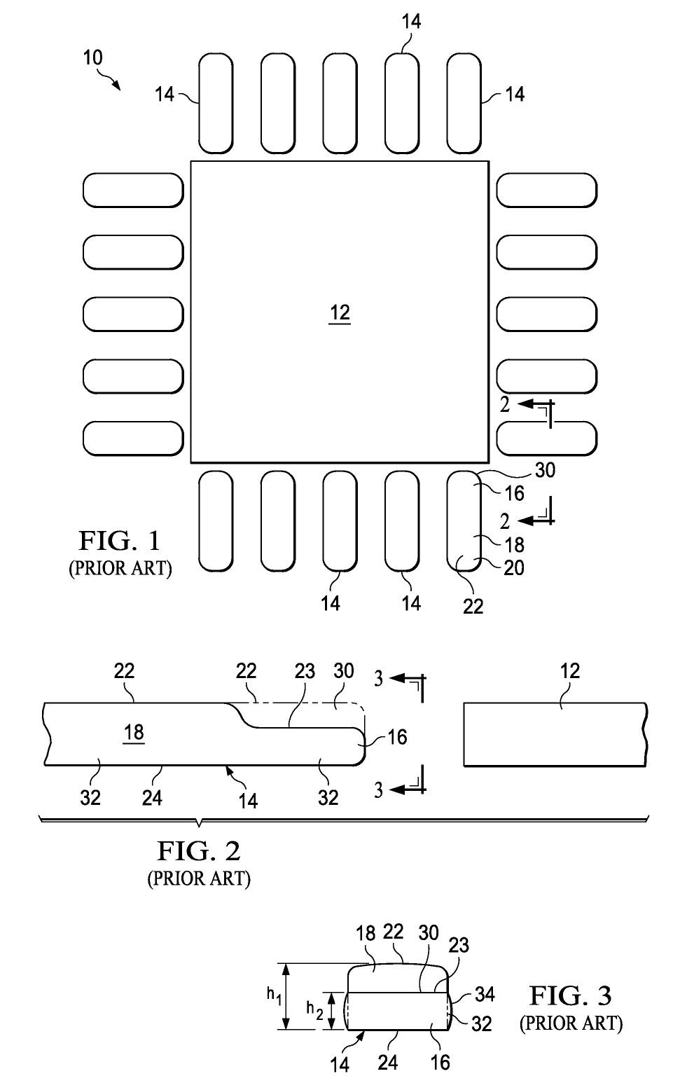

FIG. 1 illustrates a conventional lead frame 10 having a die pad 12 and a plurality of lead fingers or leads 14. Each lead comprises a proximal end tip portion 16 positioned adjacent to the die pad 12. Each lead 14 also comprises an intermediate portion 18 and a distal end portion 20. Each lead 14 has a top surface 22 and a bottom surface 24. As shown by dashed lines in FIG. 2, prior to coining, the top surface 22 is substantially continuous from the distal end portion 20 to the proximal end tip portion 16, i.e., the height (thickness) of the lead is constant from one end to the other. A coining operation creates a reduced thickness portion 30 (sometimes referred to as “coined portion 30” or “reduced height portion 30”) at the proximal end tip portion 16. As best shown by FIG. 3, the height h₂ of the coined portion 30 is conventionally about 30% less than the height h₁ of the lead 14 prior to coining. As may be seen from FIG. 3, the top surface 22 of a lead 14 that has been produced by stamp cutting is typically rounded like the top of a loaf of bread. The reason for coining the end tip portion 16 of a conventional lead 14 is to provide a flat top surface 23. A flat top surface 23 enables a better weld to be formed thereon when a bond wire is stitch bonded to the surface 23. As also shown by FIG. 3, after coining, the side wall 32 in the end tip portion 16 typically bulges somewhat, as compared to the side wall 32 in the uncoined intermediate portion 18.

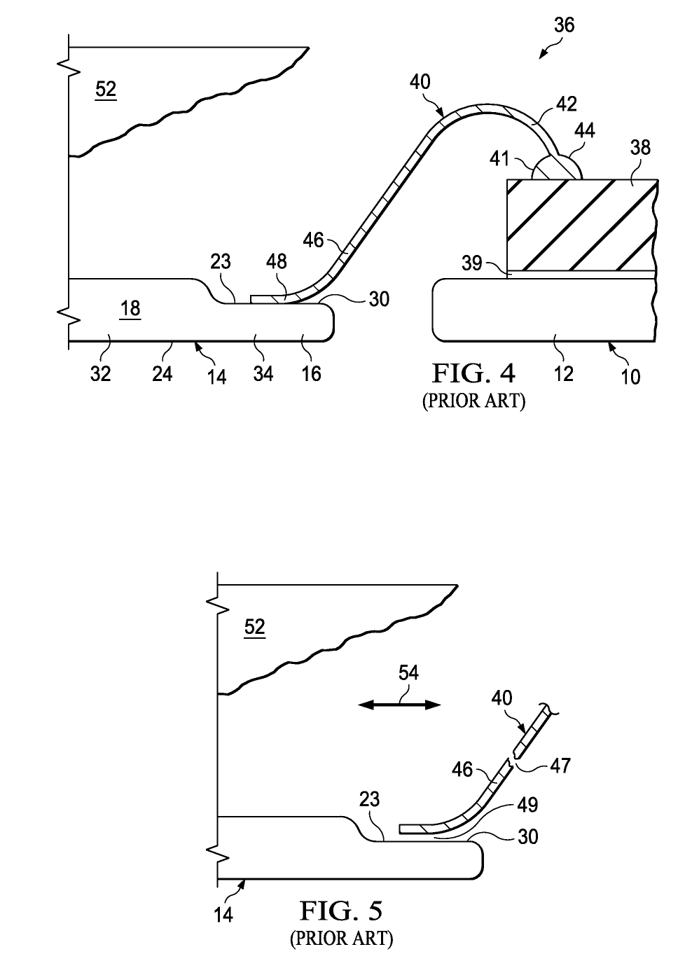

FIG. 4 illustrates a conventional integrated circuit package 36 produced using a conventional lead frame 10 such as illustrated in FIGS. 1-3. Integrated circuit package 36 has a die 38 attached to the die pad 12 by conventional die bonding material 39 such as silver epoxy or nonconductive epoxy. A die contact pad 41 is electrically connected to a lead 14 by a bond wire 40. The bond wire has a first end 42 which is welded to the die contact pad 41, typically by a ball bond 44. The bond wire 40 has a second end 46 that is welded to the proximal end tip portion 16/coined portion 30 by a stitch bond 48. Wire bonding technology is well known in the art. Ball bonds and stitch bonds are produced by a tool known as a capillary (not shown). The IC package 36 includes a layer of encapsulant 52 which covers the die 38, bond wire 40 and a portion of the lead frame 10. Bond wires of IC packages have traditionally been made from gold but more recently are often made from copper. The lead frame 10 is typically made from a copper alloy, such as CDA 194, that is plated overall with first nickel (˜0.5 um), then palladium (˜0.01 um) and finally with gold (˜0.003 um). This leadframe structure provides a wire bondable and solderable surface. Alternatively, the Cu alloy leadframe can be plated with a silver spot or spots in the areas for stitch bonding, this type of leadframe requires plating, typically with tin, after encapsulation to ensure solderability of the leads outside the plastic.

As illustrated in FIG. 5, relative movement 54 of the encapsulating layer 52 with respect to a lead 14 and bond wire 40 can cause a break 47 in the bond wire 40 or a broken stitch bond 49. Applicants have discovered that the use of copper bond wires has increased the frequency of such stitch bond failures. One method used in an attempt to prevent such stitch bond failures 49 is to roughen the top surface of the lead frame 10 to produce better adhesion between the encapsulating layer 52 and the lead frame 10. However, such roughening can negatively impact wire bonding. Vision systems, which detect the lead position for bonding, have trouble seeing a rough surface. Also, a rough surface shortens capillary life and increases the chance that micro-contaminants will be left on the rough surface, which can negatively affect capillary life and bonding consistency. The selective roughening of the lead frame surface has been suggested such that the bond fingers coined areas 30 are left smooth; however, this has not been feasible because the dimensions of the lead frame 10 prevent masking such small areas, particularly since the tips are coined. The coined surface 23 is on a different plane than the top surface 22 that will be placed in contact with a plating mask. Rough surfaces also tend to show more “resin bleed” which occurs when the resin component of the die attach layer 39 separates from the remainder of the die attach layer 39 and spreads over the surface of the die pad. Such resin bleed can degrade moisture level sensitivity by lessening encapsulant adhesion to the leadframe finish and can interfere with down bonds to the die pad.

Applicants have discovered that the problem of stitch bond failure described above may be overcome by substantially reducing the lead tip thickness, i.e., by reducing the lead tip thickness by over 50%, for example, reducing the thickness by 55%, 60%, 65%, 70% or more.

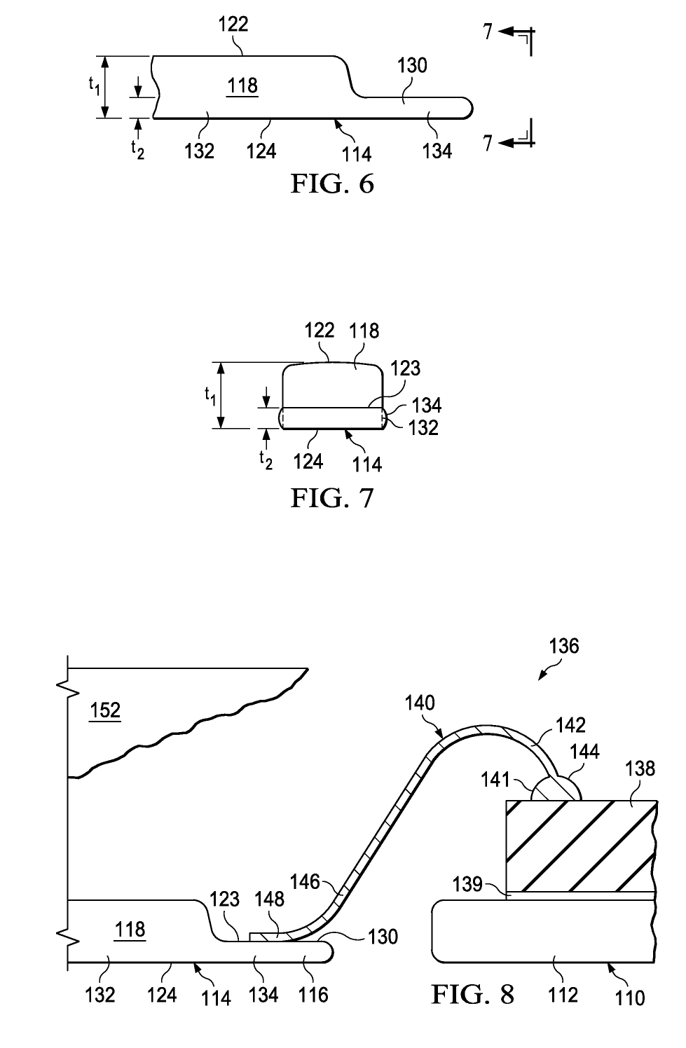

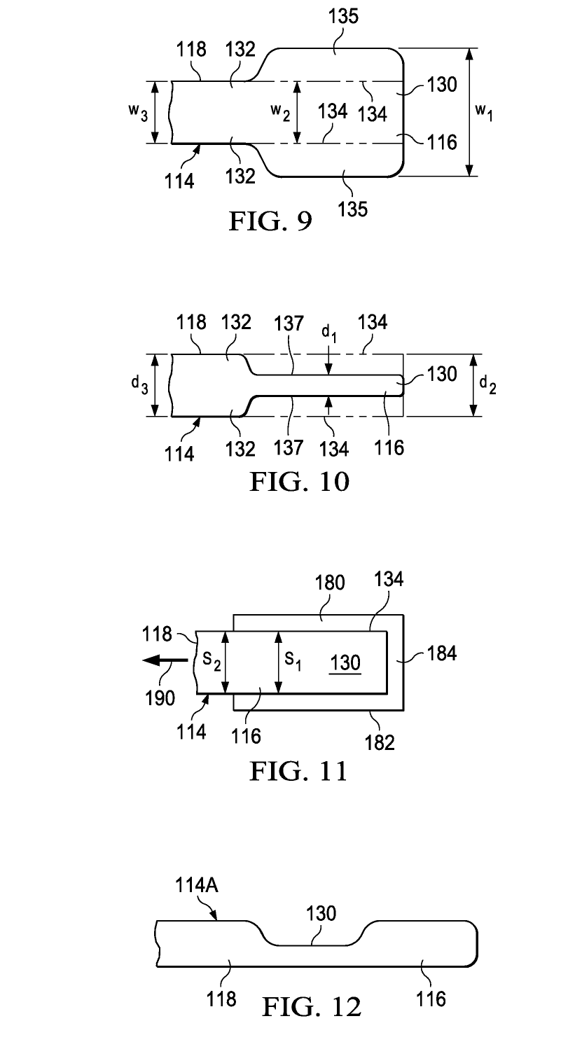

FIG. 6 illustrates a lead 114 which may be the same as the conventional leads 14 in FIGS. 1-5, except for the lead tip reduction. In FIG. 6, the lead tip 130 has been coined to a height or thickness t₂ that may be 70% less than the thickness t₁ of the lead intermediate portion 118. FIG. 7 is an end view of lead 114. It will be noted that in FIG. 7 the side wall 134 in the proximal end tip portion 116 may be approximately the same width as that of the side wall 132 of the intermediate portion 118. With the side wall 134 having approximately the same width as the side wall 132 of the remainder of the lead, the lead finger 114 typically will not come into contact with adjacent lead fingers 114. However, as illustrated in FIG. 9, after the initial coining of a lead end tip portion 116 the width w₁, i.e., the distance between the side walls 135 of the coined portion 130, is substantially larger than the distance w₂ between side walls 132 of the intermediate portion 118. This substantial increase in width is caused by the greater movement of metal in a coining operation that reduces the thickness of the tip portion 130 by more than 50% and as much as 70%. In order to avoid interference with adjacent leads 114, the lead tip 116 of FIG. 9 may be trimmed, as by using a conventional cutting punch and die (not shown) such that the final width w₂ of the tip portion 116 is approximately the same as the width w₃ of the intermediate portion 118. An added benefit which is obtained by such trimming of excess metal is that the tip region 116 now has a lower thermal mass and heats faster during wire bonding. Thus the time that it takes to make a stitch bond may be reduced and the quality of the stitch bond is improved.

As illustrated in FIG. 10, another way of maintaining the width of the tip portion 130 approximately the same as that of the intermediate portion 118 is to initially die cut the tip portion 116 to a width d₁ that is substantially smaller than the width d₃ of the intermediate portion 118. The width d₁ is selected such that after coining the width d₂ of the tip portion 116 will be approximately equal to the width d₃ of the intermediate portion 118. Thus in FIG. 10, rather than die cutting the tip after coining, the tip 116 is cut prior to the coining operation as by using a conventional cutting die.

Another method of maintaining the width s₁ of the lead tip 116 approximately equal to the width s₂ of the intermediate portion 118 is to confine the tip 116 between lateral walls 180, 182 that have sufficient strength and rigidity to withstand the lateral expansion of the die tip 130. As a result, the metal flow in the lead 114 will be in a direction 190 toward the distal end of the lead 114. Such lengthening of the lead 114 is typically not a problem since distal end portions of a lead 114 are often trimmed off at a later stage of IC package formation. To prevent the tip 116 from moving in the direction opposite 190, a further restraining wall 184 may also be provided as with the unitary U-shaped structure shown.

The above described method of substantially reducing lead tip thickness to prevent stitch bond delamination may be performed using conventional tools and thus it adds little if any production costs. For example, the coining operation performed by the new method can simply be performed at a higher pressure than used during prior art coining operations.

A reduced thickness portion 130 which is formed at the proximal end tip portion 116 of a lead 114 has been described herein. It will also be appreciated that such a reduced thickness portion 130 could be produced in the lead 114 at another portion of the lead for example an intermediate portion 118 of the lead if for some reason coining the tip portion 116 were inconvenient or impractical for a particular lead frame configuration. Such a lead 114A is shown in FIG. 12.

FIG. 8 shows an IC package 136 which may be substantially the same as the package described above with respect to FIG. 4, except that the tip portion 116 has a substantially reduced thickness as compared to that of FIG. 4, i.e., the reduced thickness region 130 at least 50% thinner than the thickness of intermediate portion 118. As a result, the stitch bond 148 formed in the reduced thickness region 130 is less likely to delaminate than the stitch bond 48 formed in the prior art. One reason for this is that the substantially reduced thickness region 130 is weaker than the corresponding reduced height region 30 of the prior art and, as a result, tends to move with the surrounding encapsulant layer 152. Applicant notes that providing such a substantially reduced thickness region, i.e., a region reduced by over 50% and by as much as 70% or more is taught away from in the prior art in order to avoid mechanical damage of the proximal end tip portion 16. In other words, in the prior art reducing the height of the tip portion 116 was only used to provide a flat surface 23 for stitch bonding. It was not provided, as in the present case, to prevent stitch bond failure. Thus, reducing the height more than was necessary to provide a flat surface was considered undesirable because a substantially thinned end portion has a greater tendency to mechanically deform or bend out of-plane, Also the tip portion becomes wider the more it is coined and thus is more likely to short out on adjacent leads—another reason why large tip thickness reduction was taught away from in the prior art.

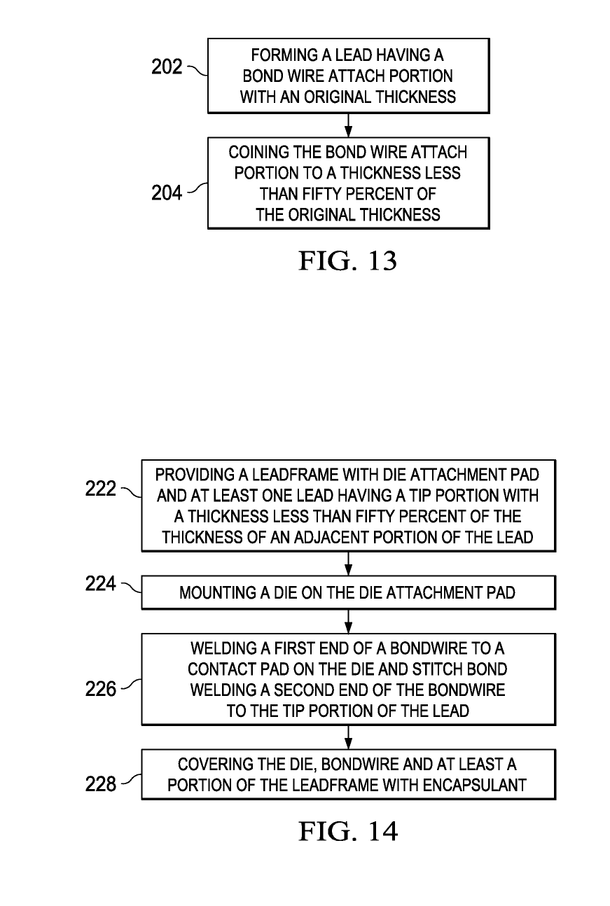

It will be appreciated from the above disclosure that one method of forming a lead frame may comprise as shown in FIG. 13: forming a lead having a bond wire attach portion with an original thickness, as shown in block 202. The method may also include coining the bond wire attach portion to a thickness less than 50% of the original thickness, as shown at block 204.

It will also be appreciated that a method of forming an integrated circuit package has been disclosed as shown by FIG. 14. The method may include providing a lead frame with die attachment pad and at least one lead having a tip portion with a thickness less than 50% of that of an adjacent portion of the lead, as shown at block 222. The method may also include as shown at block 224 mounting a die on the die attachment pad. The method may further include, as shown at block 226, welding a first end of a bond wire to a contact pad on the die and stitch bond welding a second end of the bond wire to the tip portion of the lead. The method may also include as shown at 228, covering the die, bond wire and at least a portion of the lead frame with encapsulant.

This disclosure has expressly described, in detail, certain embodiments of leadframes and an integrated circuit packages and parts thereof and related methods that embody applicants' inventive concepts. It will be obvious to persons skilled in the art, after reading this disclosure, that applicants' inventive concepts may be otherwise embodied. The appended claims are intended to be broadly construed to cover all such alternative embodiments, except as limited by the prior art.

What is claimed is:

1. A method of forming a leadframe comprising:
forming a lead having a bond wire attach portion with an original thickness; and
coining the bond wire attach portion to a thickness less than 50% of the original thickness.

2. The method of claim 2 wherein said forming a lead comprises forming a lead with a bond wire attach portion positioned at a tip end portion of the lead.

3. The method of claim 1 further comprising trimming the bond wire attach portion of the lead.

4. The method of claim 3 wherein said trimming the bond wire attach portion of the lead comprises trimming the width of the bond wire attach portion prior to said coining.

5. The method of claim 3 wherein said trimming the bond wire attach portion of the lead comprises trimming the width of the bond wire attach portion subsequent to said coining.

6. The method of claim 1 further comprising constraining lateral expansion of the tip end portion of the lead during said coining.

7. A leadframe comprising:
a die attachment pad; and
a lead having a bondwire attach portion with a thickness less than 50% of the thickness of an adjacent portion of the lead.

8. The leadframe of claim 7 wherein said bondwire attach portion has a thickness less than 40% of the thickness of an adjacent portion of the lead.

9. The leadframe of claim 7 wherein said bondwire attach portion has a thickness less than 30% of the thickness of an adjacent portion of the lead.

10. The leadframe of claim 7 wherein said leadframe comprises copper alloy base metal.

11. An integrated circuit package comprising:
a leadframe comprising a die attachment pad and a lead having a bondwire attach portion with a thickness less than 50% of the thickness of an adjacent portion of the lead;
a die mounted on said die attachment pad and having a contact pad thereon; and
a bondwire having a first end welded to said contact pad and a second end welded to said bondwire attach portion of said lead.

12. The integrated circuit package of claim 11 further comprising:
a layer of encapsulant encapsulating said die, said bondwire and at least a portion of said leadframe.

13. The integrated circuit package of claim 11 wherein said bondwire comprises copper.

14. The integrated circuit package of claim 11 wherein said leadframe comprises copper alloy base metal.

15. The integrated circuit package of claim 11 wherein said second end of said bondwire is welded to said contact pad with a stitch weld.

16. The integrated circuit package of claim 11 wherein said bondwire attach portion of said lead is located at a tip end portion of said lead.

17. The integrated circuit package of claim 11 wherein said bondwire attach portion has a thickness less than 40% of the thickness of an adjacent portion of the lead.

18. The integrated circuit package of claim 11 wherein said bondwire attach portion has a thickness less than 30% of the thickness of an adjacent portion of the lead.

19. A method of forming an integrated circuit package comprising:
providing a leadframe with die attachment pad and at least one lead having a tip portion with a thickness less than 50% of the that of an adjacent portion of the lead;
mounting a die on the die attachment pad;
welding a first end of a bondwire to a contact pad on the die and stitch bond welding a second end of the bondwire to the tip portion of the lead; and
covering the die, bondwire and at least a portion of the leadframe with encapsulant.

20. The method of claim 19 wherein said welding a second end of the bondwire to the tip portion of the lead comprises welding a second end of a copper bondwire to a tip portion of a copper lead.
